(19) United States
(12) Patent Application Publication
(10) Pub. No.: US 2024/0153820 A1
(43) Pub. Date: May 9, 2024

(54) PROCESSING METHOD OF PROCESSING APPARATUS AND PROCESSING SYSTEM

(71) Applicant: PlayNitride Display Co., Ltd., MiaoLi County (TW)

(72) Inventors: Chang-Rong Lin, MiaoLi County (TW); Ching-Liang Lin, MiaoLi County (TW)

(73) Assignee: PlayNitride Display Co., Ltd., MiaoLi County (TW)

(21) Appl. No.: 17/994,412

(22) Filed: Nov. 28, 2022

(30) Foreign Application Priority Data
Nov. 7, 2022 (TW) 111142343

(51) Int. Cl. H01L 21/768; B23K 26/53

(52) U.S. Cl. CPC H01L 21/76894; B23K 26/53

(57) ABSTRACT

A processing method of a processing apparatus is provided, including step 1, step 2, step 3, and step 4. Step 1 is providing an object having a processed surface, and dividing the processed surface into multiple processed regions, where there is at least one workpiece on each processed region. Step 2 is performing path computation according to the workpiece on each processed region, and generating a processing path in each processed region, where the processing paths in the processed regions are different from each other. Step 3 is performing processing operation by a processing apparatus according to the processing path in one of the processed regions obtained from step 2. Step 4 is moving the processing apparatus to a next processed region after finishing the processing operation on each workpiece in the one of the processed regions. A processing system is also provided.

### CROSS-REFERENCE TO RELATED APPLICATION

This application claims the priority benefit of Taiwanese application no. 111142343, filed on Nov. 7, 2022. The entirety of the above-mentioned patent application is hereby incorporated by reference herein and made a part of this specification.

### BACKGROUND

### Technical Field

The disclosure relates to a processing method of a processing apparatus and a processing system.

### Description of Related Art

During manufacturing of chips (e.g., micro light-emitting diode chips), when a detection apparatus finds a defective chip on a substrate, the chip may be removed from the substrate by a laser lift-off process, for example. At this time, a laser apparatus facing the chips, for example, scans all positions of the chips, and emits a laser beam to perform laser lift-off when encountering a defective position. However, a scanning path for such whole-surface scanning is relatively long and takes a relatively great amount time.

Another approach is computing a relatively optimal path of the laser apparatus scanning over defective locations each time a chip is processed. However, a new relatively optimal path is required to be re-computed each time a chip is replaced, resulting in a relatively long computation time.

### SUMMARY

The disclosure provides a processing method of a processing apparatus, effectively reducing processing time and computation time.

The disclosure provides a processing system, effectively reducing processing time and computation time.

An embodiment of the disclosure proposes a processing method of a processing apparatus, including step 1, step 2, step 3, and step 4. In step 1, an object provided, the object has a processed surface, and the processed surface is divided into a plurality of processed regions. There is at least one workpiece on each of the processed regions, and an intersection of the processed regions is an empty set. In step 2, path computation is performed according to the at least one workpiece on each of the processed regions, and a processing path in each of the processed regions is generated. The processing paths in the processed regions are different from each other. In step 3, processing operation is performed by a processing apparatus according to the processing path in one of the processed regions obtained from step 2. In step 4, the processing apparatus is moved to a next processed region after finishing the processing operation on each of the at least one workpiece in the one of the processed regions.

An embodiment of the disclosure proposes a processing system configured to process an object. The object has a processed surface. The processing system includes a computation unit, a processing apparatus, and a control unit. The computation unit is configured to divide the processed surface into a plurality of processed regions. There is at least one workpiece on each of the processed regions, and an intersection of the processed regions is an empty set. The computation unit is further configured to perform path computation according to the at least one workpiece on each of the processed regions, and to generate a processing path in each of the processed regions. The processing paths in the processed regions are different from each other. The control unit is configured to control the processing apparatus to perform processing operation according to the processing path in one of the processed regions obtained from computation by the computation unit. After the processing apparatus finishes the processing operation on each of the at least one workpiece in the one of the processed regions, the control unit is configured to control the processing apparatus to move to the processing path in a next processed region to perform processing operation.

In the processing method of a processing apparatus and the processing system of the embodiments of the disclosure, path computation is performed according to the at least one workpiece on each processed region, and the processing path in each processed region is generated. In addition, after finishing the processing operations on all workpieces in one processed region, the processing apparatus is then moved to the next processed region. Accordingly, the processing method of a processing apparatus and the processing system of the embodiments of the disclosure may effectively reduce the computation time and also effectively reduce the processing time.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic structural diagram of a processing system of an embodiment of the disclosure.

FIG. 2 is a flowchart of a processing method of a processing apparatus of an embodiment of the disclosure.

FIG. 3 and FIG. 4 are schematic diagrams of processing paths of the processing method of a processing apparatus of FIG. 2.

FIG. 5 shows a sub-region of a processed region in FIG. 3 or FIG. 4.

FIG. 6 shows an alternative arrangement of processed regions.

### DESCRIPTION OF THE EMBODIMENTS

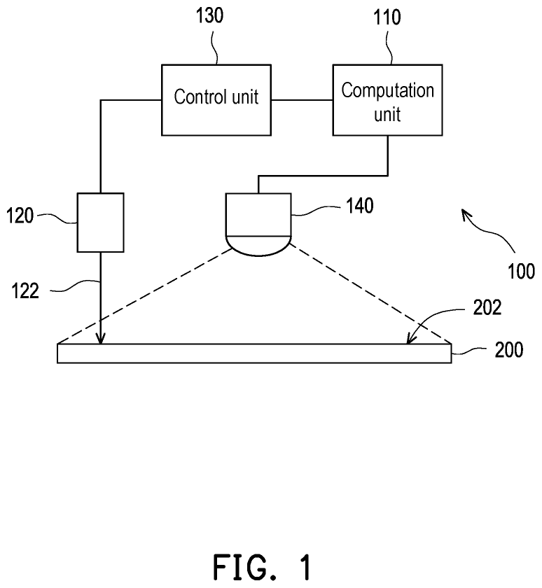

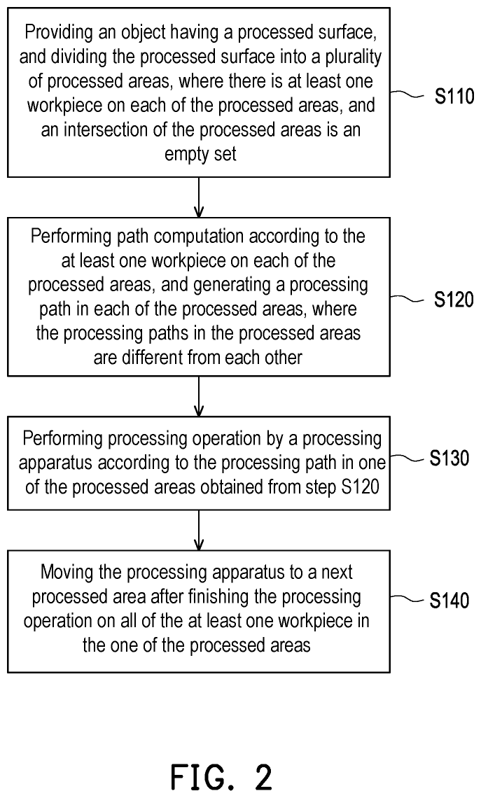

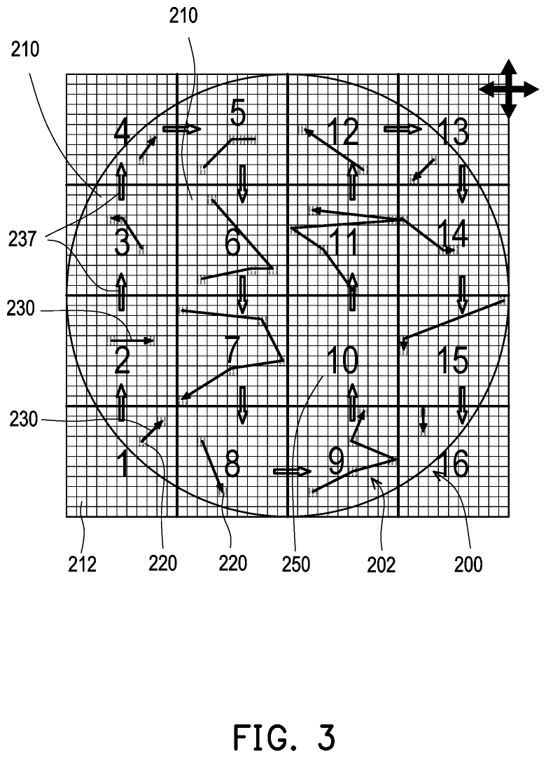

FIG. 1 is a schematic structural diagram of a processing system of an embodiment of the disclosure, FIG. 2 is a flowchart of a processing method of a processing apparatus of an embodiment of the disclosure, and FIG. 3 and FIG. 4 are schematic diagrams of processing paths of the processing method of a processing apparatus of FIG. 2. With reference to FIG. 1 to FIG. 4, in this embodiment, a processing system 100 may be configured to perform the processing method of a processing apparatus of FIG. 2. The processing system 100 is configured to process an object 200 that has a processed surface 202. In this embodiment, for example, the object 200 is a substrate where a plurality of electronic components or conductive circuits are disposed on the processed surface 202. For example, the electronic components are micro light-emitting diodes or other forms of electronic components, and the substrate is a temporary substrate or a display backplane.

The processing system 100 includes a computation unit 110, a processing apparatus 120, and a control unit 130. The computation unit 110 is configured to divide the processed surface 202 into a plurality of processed regions 210 (represented by medium-sized grids of FIG. 3, for example). For example, FIG. 3 shows the processed surface 202 being divided into 4×4 (i.e., 16) processed regions 210. There is at least one workpiece 220 on the processed regions 210. In this embodiment, the workpiece 220 is a defective electronic component or conductive circuit, for example, a defective micro light-emitting diode, sensor, or conductive circuit. An intersection of the processed regions 210 is an empty set. In other words, the processed regions do no partially overlap or completely overlap.

The computation unit 110 is further configured to perform path computation according to the at least one workpiece 220 on each processed region 210, and generate a processing path 230 in each processed region 210. The processing paths 230 in the processed regions 210 are different from each other, as shown in FIG. 3.

The control unit 130 is electrically connected to the computation unit 110 and the processing apparatus 120, and is configured to control the processing apparatus 120 to perform processing operation according to the processing path 230 in one of the processed regions 210 obtained from computation by the computation unit 110. After the processing apparatus 120 finishes the processing operation on each of the at least one workpiece 220 in the one of the processed regions 210, the control unit 130 is configured to control the processing apparatus 120 to move to the processing path 230 in the next processed region 210 to perform processing operation. In this embodiment, the processing apparatus 120 includes a laser apparatus, and the processing operation includes component removal. For example, the processing apparatus 120 emits a laser beam 122 to perform a laser lift-off process, so that the workpiece 220 (e.g., a defective micro light-emitting diode) is detached from a substrate 200.

In this embodiment, the processing method of a processing apparatus includes step S110, step S120, step S130, and step S140. Step S110 is providing the object 200, the object 200 having the processed surface 202, and dividing the processed surface 202 into a plurality of processed regions 210, where there is at least one workpiece 220 on each processed region 210, and an intersection of the processed regions 210 is an empty set. Step S120 is performing path computation according to the at least one workpiece 220 on each processed region 210, and generating the processing path 230 in each processed region 210, where the processing paths 230 in the processed regions 210 are different from each other. Step S130 is performing processing operation by the processing apparatus 120 according to the processing path 230 in one of the processed regions 210 obtained from step S120. Step S140 is moving the processing apparatus 120 to the next processed region 210 after finishing the processing operation on each of the at least one workpiece 220 in the one of the processed regions 210. In this embodiment, the sequence of the processing apparatus 120 moving to the next processed region 210 and then processing the processed regions 210 is as shown by a movement path 237 (a path arrow), as shown in FIG. 3 and FIG. 4. In an embodiment, the same processed region 210 is not processed back and forth in the sequence of processing. In FIG. 3 and FIG. 4, Nos. 1 to 16 is the sequence in which the processing apparatus 120 processes the processed regions 210, namely first processing the processed region 210 numbered 1, then, following the movement path 237, processing the processed region 210 numbered 2, then processing the processed region 210 numbered 3, and then sequentially processing the processed regions 210 numbered 4 to 16. In this embodiment, the movement of the processing apparatus 120 relative to the processed regions 210 may encompass the case where the processing apparatus 120 does not move while the processed regions 210 are moved by the movement of a stage carrying the substrate 200, or the case where the substrate 200 does not move while the processing apparatus 120 moves. Accordingly, “moving the processing apparatus 120 to the next processed region 210” described above may refer to the case where the processing apparatus 120 does not move while a stage moves the substrate 200, or the case where the substrate 200 does not move while the processing apparatus 120 moves. In addition, in an embodiment, the processed regions 210 have an equal area.

In this embodiment, in the processing method of a processing apparatus and the processing system 100, path computation is performed according to the at least one workpiece 220 on each processed region 210, and the processing path 230 in each processed region 210 is generated. In addition, after finishing the processing operation on each of the at least one workpiece 220 in one processed region 210, the processing apparatus 120 is then moved to the next processed region 210. Accordingly, the processing method of a processing apparatus and the processing system of this embodiment may effectively reduce the computation time and also effectively reduce the processing time. In other words, in this embodiment, the processing method of a processing apparatus and the processing system 100 may be accompanied with software (executed by the computation unit 110, for example) in optimizing the processing path 230 in advance to reduce the idle running time of the processing apparatus 120. In addition, since optimizing the processing path 230 is by performing computation for divided regions (i.e., divided into a plurality of processed regions 210), and the processed regions 210 is processed in in a fixed sequence (e.g., the sequence indicated by the movement path 237), computation may be simplified and computation time may be saved accordingly. Compared with the conventional computation on an entire processed surface, at least about 40% of time may be saved.

In an embodiment, as shown in FIG. 3, in each processed region 210, the workpiece 220 at the bottommost-leftmost corner relative to the movement path 237 entering this region is consistently taken as the starting point of the processing path 230, sequentially linking first rows and then columns from left to right according to the direction of the movement path 237 entering this region. During path planning, it is only necessary to consider which workpiece 220 is the workpiece at the bottommost-leftmost corner to be taken as the starting point, without considering the coordinates of the last point in the previous processed region 210. As such, the computation burden can be reduced.

In an embodiment, as shown in FIG. 4, after step S130 and before step S140, the processing apparatus 120 moves between the adjacent processed regions 210 in a linking path 235. The linking path 235 links the processing paths 230, and the linking path 235 and the processing paths 230 form a non-overlapping path, where the end point in the previous processed region 210 is connected to the starting point in the subsequent processed region 210. At this time, the processing apparatus 120 moves and the stage carrying the substrate 200 also moves so that the processing apparatus moves and processes.

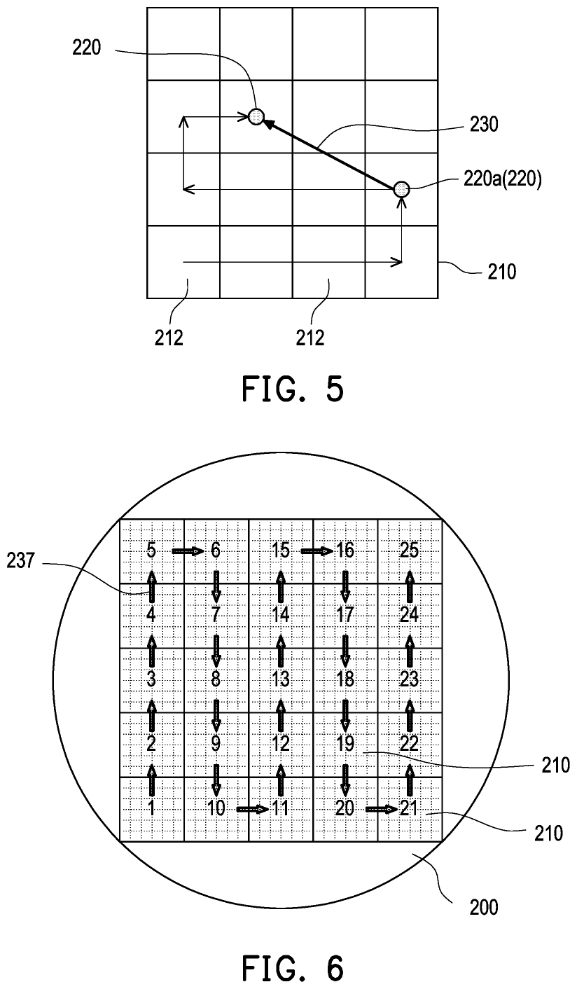

In this embodiment, the processed surface 202 includes M×N processed regions 210, where M+N>2 and both M and N are positive integers, and the processing apparatus 120 sequentially moves in the processed regions 210. In an embodiment, 2≤M≤5 and 2≤N≤5, and the processed regions 210 are arranged into an array. In FIG. 3 and FIG. 4, 16 processed regions 210 are taken as an example. Nonetheless, in other embodiments, the processed surface 202 may also be divided into 25 processed regions 210 or into other numbers of processed regions 210. For example, FIG. 6 shows 25 processed regions 210. Division into 25 processed regions 210 saves the most time, division into more than 25 processed regions 210 does not show much efficiency, and division into less than 4 processed regions 210 saves relatively less time. The shape of the processed region 210 may be a polygon, a rectangle, a square, an equilateral triangle, a hexagon, or other suitable geometric shapes. In addition, in this embodiment, an area ratio of each processed region 210 to the processed surface 202 (or to the object 200) falls within a range from 0.04 to 0.25.

In this embodiment, the processed surface 202 further includes at least one normal region 250 among the adjacent processed regions 210, and the number of workpieces 220 in the at least one normal region 250 is 0, as shown in FIG. 3 and FIG. 4. In this embodiment, the processing apparatus 120 scans over the at least one normal region 250 without processing when the processing apparatus 120 is moved to the next processed region 210. The one of the processed regions 210 in step S130 and the next processed region 210 in step S140 are adjacent to two sides of the at least one normal region 250, as shown in FIG. 3 and FIG. 4. In this embodiment, the normal region 250 is connected to the processed regions 210 to form the processed surface 202. In an embodiment, the normal region 250 and the processed region 210 have an equal area.

In this embodiment, the at least one workpiece 220 in one processed region 210 includes a plurality of workpieces 220, and the processing path 230 is a connection path of the workpieces 220 that minimizes a time of the processing operation performed by the processing apparatus 120 in the processed region 210. In an embodiment, the processing path 230 is a path connected between the workpieces 220 with a minimum distance, and the processing path 230 is not crossed. In addition, in an embodiment, the at least one workpiece 220 in one processed region 210 includes one workpiece 220, and the processing path 230 is the location of the workpiece.

In an embodiment, for example, the computation unit 110 and the control unit 130 are each a central processing unit (CPU), a microprocessor, a digital signal processor (DSP), a programmable controller, a programmable logic device (PLD), or any other similar device or a combination of these devices, which is not limited by the disclosure. In addition, in an embodiment, the functions of the computation unit 110 and the control unit 130 may be implemented as a plurality of programming codes. The programming codes may be stored in a memory, and may be executed by the computation unit 110 and the control unit 130.

Alternatively, in an embodiment, the functions of the computation unit 110 and the control unit 130 may be implemented as one or more circuits. The disclosure does not limit implementing the functions of the computation unit 110 and the control unit 130 in the form of software or hardware. In an embodiment, the computation unit 110 and the control unit 130 may also be integrated into the same controller.

In this embodiment, the processing method of a processing apparatus further includes, before step S110, detecting the processed surface 202 to obtain a position of the at least one workpiece 220 on the processed surface 202, for example, obtaining the positions of all workpieces 220 on the processed surface 202. In this embodiment, the processing system 100 further includes a detection unit 140 configured to detect the processed surface 202 to obtain the position of the workpiece 220 on the processed surface 202. For example, the detection unit 140 is an automated optical inspection device or other devices that detects an image of the processed surface 202. The detection unit 140 may be electrically connected to the computation unit 110 to send the captured image signal to the computation unit 110 for analysis.

In an embodiment, the processing method of a processing apparatus further includes dividing the processed surface 202 into a plurality of detection regions, and detecting each of the detection regions to obtain the position of the at least one workpiece 220 on the processed surface 202 (for example, obtaining the positions of all workpieces 220 on the processed surface 202). In an embodiment, the detection regions respectively overlap the processed regions 210 on the processed surface 202. Specifically, for example, the divided detection regions on the processed surface respectively corresponds to the subsequent processed regions 210, and the detection regions and the processed region 210 have an equal area and completely overlap, to save the time for subsequent division into the processed regions.

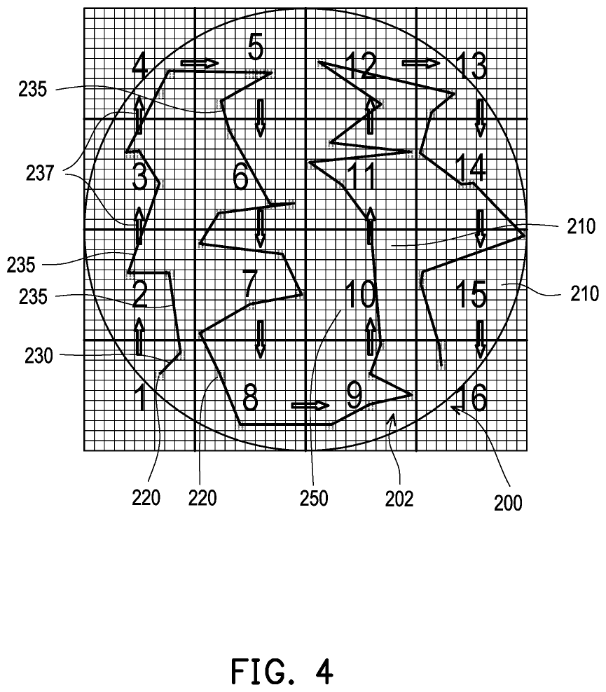

In this embodiment, each processed region 210 includes m×n sub-regions 212, where m+n>2 and m and n are positive integers. The processing method of a processing apparatus further includes sequentially performing path computation on the m×n sub-regions 212. FIG. shows a relatively small number of 4×4 sub-regions 212 for exemplifying. Each sub-region is correspondingly equipped with workpieces that need to be processed (e.g., defective micro light-emitting diodes) and components that do not need to be processed (e.g., normal micro light-emitting diodes). A first workpiece 220a on the 4×4 sub-regions 212 is set to a first workpiece to be processed on the processing path 230 when performing the path computation, and the processing path 230 of the processing apparatus 120 performing the processing operation on the workpiece 220 on the processed region 210 is generated. Nonetheless, the number of divided sub-regions is not limited to FIG. 5, and may be 11×11 sub-regions 212 as schematically shown in FIG. 3, or may be 6×6 sub-regions as schematically shown in FIG. 6. The number of divided sub-regions is subject to the number of electronic components or conductive circuits disposed on the object 200.

In this embodiment, the boundary of the substrate 200 is an inscribed circle of the overall boundary of the processed regions 210. As such, all the area on the substrate 200 can be fully utilized. This configuration is relatively flexible, and may correspond to substrates 200 of different shapes. Nonetheless, in another embodiment, the boundary of the substrate 200 may also be the circumscribed circle of the overall boundary of the processed regions 210, as shown in FIG. 6. This is a case where no workpieces 220 or relatively less workpieces 220 are utilized in the peripheral region of the substrate 200, so they do not need to be included in the detection regions or processed regions, reducing the computation time. In FIG. 6, Nos. 1 to 25 is the sequence in which the processing apparatus 120 processes the processed regions 210. Division into 25 processed regions 210 as shown in FIG. 6 may save the most working time, division into more than 25 processed regions 210 does not show much efficiency, and division into less than 4 processed regions 210 saves relatively less time. Nonetheless, the disclosure is not limited thereto.

In summary of the foregoing, in the processing method of a processing apparatus and the processing system of the embodiments of the disclosure, path computation is performed according to the at least one workpiece on each processed region, and the processing path in each processed region is generated. In addition, after finishing the processing operations on all workpieces in one processed region, the processing apparatus is then moved to the next processed region. Accordingly, the processing method of a processing apparatus and the processing system of the embodiments of the disclosure may effectively reduce the computation time and also effectively reduce the processing time.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A processing method of a processing apparatus, the method comprising:
step 1: providing an object, the object having a processed surface, and dividing the processed surface into a plurality of processed regions, wherein there is at least one workpiece on each of the processed regions, and an intersection of the processed regions is an empty set;
step 2: performing path computation according to the at least one workpiece on each of the processed regions, and generating a processing path in each of the processed regions, wherein the processing paths in the processed regions are different from each other;
step 3: performing processing operation by a processing apparatus according to the processing path in one of the processed regions obtained from step 2; and
step 4: moving the processing apparatus to a next processed region after finishing the processing operation on each of the at least one workpiece in the one of the processed regions.

2. The processing method according to claim 1, wherein, after step 3 and before step 4, the processing apparatus moves between adjacent ones of the processed regions in a linking path, the linking path links the processing paths in the processed regions, and the linking path and the processing paths of the processed regions form a non-overlapping path.

3. The processing method according to claim 1, wherein the processed surface comprises M×N processed regions, where M+N>2 and both M and N are positive integers, and the processing apparatus sequentially moves in the processed regions.

4. The processing method according to claim 1, wherein an area ratio of each of the processed regions to the processed surface falls within a range from 0.04 to 0.25.

5. The processing method according to claim 1, wherein the processed surface further comprises at least one normal region among adjacent ones of the processed regions, wherein the number of workpieces in the at least one normal region is zero.

6. The processing method according to claim 5, wherein, the processing apparatus scans over the at least one normal region without processing when the processing apparatus is moved to the next processed region, wherein the one of the processed regions in step 3 and the next processed region in step 4 are adjacent to two sides of the at least one normal region.

7. The processing method according to claim 1, wherein the at least one workpiece comprises a plurality of workpieces, and the processing path is a connection path of the workpieces minimizing a time of the processing operation performed by the processing apparatus in the processed region.

8. The processing method according to claim 7, wherein the processing path is a path connected between the workpieces with a minimum distance, and the processing path is not crossed.

9. The processing method according to claim 1, further comprising:
before step 1, detecting the processed surface to obtain a position of the at least one workpiece on the processed surface.

10. The processing method according to claim 9, further comprising:
dividing the processed surface into a plurality of detection regions, and detecting each of the detection regions to obtain the position of the at least one workpiece on the processed surface.

11. The processing method according to claim 10, wherein the detection regions respectively overlap the processed regions on the processed surface.

12. The processing method according to claim 1, wherein the processing apparatus comprises a laser apparatus, and the processing operation comprises component removal.

13. The processing method according to claim 1, wherein each of the processed regions comprises m×n sub-regions, where m+n>2 and m and n are positive integers,
the processing method further comprising sequentially performing path computation on the m×n sub-regions; wherein a first workpiece on the m×n sub-regions is set to a first workpiece to be processed on the processing path when performing the path computation, and the processing path of the processing apparatus performing the processing operation on the at least one workpiece on the processed region is generated.

14. A processing system configured to process an object, the object having a processed surface, the processing system comprising:
a computation unit configured to divide the processed surface into a plurality of processed regions, wherein there is at least one workpiece on each of the processed regions, and an intersection of the processed regions is an empty set, the computation unit further being configured to perform path computation according to the at least one workpiece on each of the processed regions, and to generate a processing path in each of the processed regions, wherein the processing paths in the processed regions are different from each other;
a processing apparatus; and
a control unit configured to control the processing apparatus to perform processing operation according to the processing path in one of the processed regions obtained from computation by the computation unit, wherein after the processing apparatus finishes the processing operation on each of the at least one workpiece in the one of the processed regions, the control unit is configured to control the processing apparatus to move to the processing path in a next processed region to perform processing operation.

15. The processing system according to claim 14, further comprising a detection unit configured to detect the processed surface to obtain a position of the at least one workpiece on the processed surface.
